(19) United States
(12) Patent Application Publication
(10) Pub. No.: US 2016/0065243 A1
(43) Pub. Date: Mar. 3, 2016

(54) RADIATION HARDENING ARCHITECTURAL EXTENSIONS FOR A RADIATION HARDENED BY DESIGN MICROPROCESSOR

(71) Applicants: Dan Wheeler Patterson, Scottsdale, AZ (US); Lawrence T. Clark, Phoenix, AZ (US)

(72) Inventors: Dan Wheeler Patterson, Scottsdale, AZ (US); Lawrence T. Clark, Phoenix, AZ (US)

(73) Assignee: Arizona Board of Regents on behalf of Arizona State University, Scottsdale, AZ (US)

(21) Appl. No.: 14/837,361

(22) Filed: Aug. 27, 2015

Related U.S. Application Data
(60) Provisional application No. 62/042,417, filed on Aug. 27, 2014.

(51) Int. Cl. H03M 13/11; G06F 9/30; H03M 13/00

(52) U.S. Cl. CPC H03M 13/1111; H03M 13/611; G06F 9/30145

(57) ABSTRACT

This disclosure relates generally to processors and methods of operating the same. In particular, this disclosure relates to components for correcting soft errors in a processor. In one embodiment, a processor includes an instruction decoder and an exception handler. The instruction decoder is configured to receive one or more soft error correction instructions and decode the one or more soft error correction instructions. Additionally, an exception handler is configured to execute the one or more soft error correction instructions so as to correct one or more soft errors. In this manner, the processor is capable of correcting soft errors that are the result of radiation strikes.

### RELATED APPLICATIONS

This application claims the benefit of provisional patent application Ser. No. 62/042,417, filed Aug. 27, 2014, the disclosure of which is hereby incorporated herein by reference in its entirety.

### GOVERNMENT SUPPORT

This invention was made with government support under FA9453-07-C-0186 awarded by the Air Force. The U.S. Government has certain rights in this invention.

### FIELD OF THE DISCLOSURE

This disclosure relates generally to processors and related circuitry.

### BACKGROUND

State machines built from integrated circuits need to be radiation hardened to prevent soft errors that occur when a high energy particle travels through the integrated circuit's semiconductor substrate. This is particularly important when the state machine operates in high radiation environments such as outer space. An ionizing particle traveling through the semiconductor substrate may cause a transient voltage glitch, i.e., a single event transient (SET), or may cause a sequential state element to store the wrong state, i.e., a single event upset (SEU). Therefore radiation hardening techniques are needed to protect processing circuitry from radiation to correct for soft errors.

### SUMMARY

This disclosure relates generally to processors and methods of operating the same. In particular, this disclosure relates to components for correcting soft errors in a processor. In one embodiment, a processor includes an instruction decoder and an exception handler. The instruction decoder is configured to receive one or more soft error correction instructions and decode the one or more soft error correction instructions. Additionally, an exception handler is configured to execute the one or more soft error correction instructions so as to correct one or more soft errors. In this manner, the processor is capable of correcting soft errors that are the result of radiation strikes.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a layout and floorplan of one embodiment of a processor in accordance with this disclosure.

FIG. 2 illustrates a more detailed block diagram of the processor shown in FIG. 1, which illustrates a register file, an instruction decoder and an exception handler utilized to correct soft errors.

FIG. 3 illustrates a register file cell 50 in the register file shown in FIG. 2.

FIG. 4 illustrates an exemplary description of a floorplan of the register file shown in FIG. 2.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

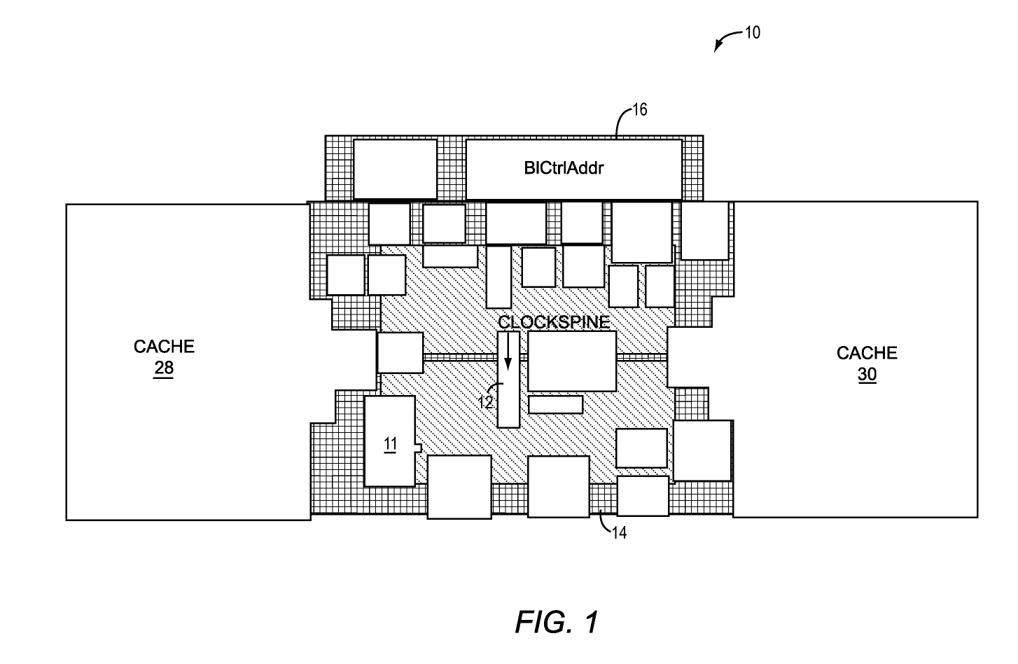

FIG. 1 illustrates a layout and floorplan of one embodiment of a processor 10 in accordance with this disclosure. As explained in further detail below, the processor 10 includes hardware decode logic (not explicitly labeled in FIG. 1) configured to receive one or more soft error correction instructions. Soft error detection may be provided in accordance with related application “Circuits and Methods For Dual Redundant Register Files With Error Detection and Correction Mechanisms;” U.S. patent application Ser. No. 12/626,488, filed Nov. 25, 2009; now U.S. Pat. No. 8,397,133, issued Mar. 12, 2013; which is incorporated herein by reference. The one or more soft error correction instructions are each configured to indicate a soft error correction procedure to be employed by the processor 10 to correct the error. A dual redundant register file 11 along with soft error checking circuitry (not explicitly labeled in FIG. 1) is provided in FIG. 1. The processor 10 also includes an exception handler (not explicitly shown in FIG. 1) that is configured to implement the one or more soft error correction instructions in order to correct one or more detected soft errors. As shown in FIG. 1, caches (e.g., an instruction cache 28, a data cache 30) provided by the processor 10 are placed on each side of the processor 10 since their interfaces then reside along the edges with the rest of the core. Routing congestion estimates are used to drive this process for placement. The caches (e.g., the instruction cache 28, data cache 30) are placed at the two sides of the chip.

A clock spine 12, which is the central clock unit, is placed near the center of the chip to limit clock route lengths and balance clock delay and skew. Triple Mode Redundant (TMR) sequential state elements and other TMR circuitry 14, which holds instructions for execution in the present architectural state, is also centrally placed to ensure adequate routing resources. A bus-interface unit 16 (the block labelled BlCtrlAddr) is placed on the periphery of the processor 10.

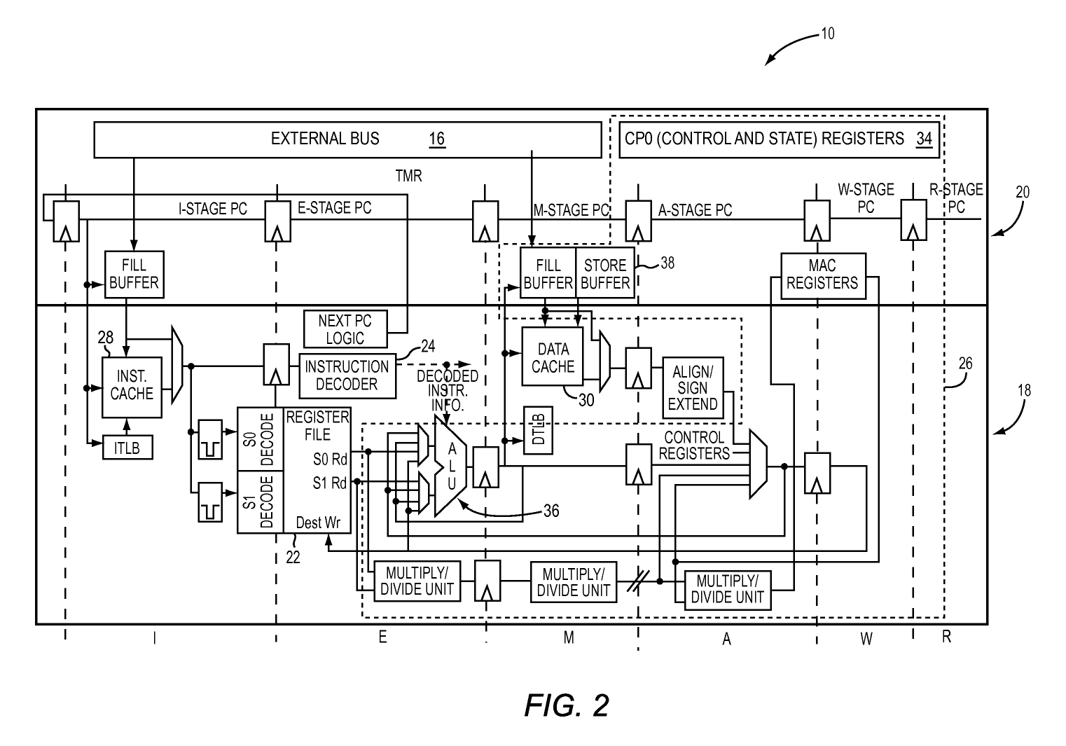

FIG. 2 illustrates a more detailed block diagram of the processor 10 shown in FIG. 1. The processor 10 includes one or more dual mode redundancy (DMR) regions 18 and one or more TMR regions 20. The circuitry within the DMR regions 18 is DMR, and the circuitry within the TMR regions 20 is TMR. Furthermore, the processor 10 includes six pipeline stages labeled I, E, M, A, W, R. Within pipeline stage E, the processor 10 includes a register file 22 and an instruction decoder 24. The instruction decoder 24 is configured to decode instructions from the register file 22, which includes soft error correction instructions. Within pipeline stages E, M, A, W, R is an exception handler 26 configured to implement the soft error correction instructions that correct soft errors, such as architectural state Single Event Upsets (SEUs).

A software rather than hardware approach is implemented by the exception handler 26 where possible to implement the software correction instructions. A detected Single Event Transient (SET) or SEU triggers an exception. The exception handler 26 repairs one or more processor states via the software instructions added to the base instruction set carried out by the processor 10. If the soft error is in the speculative pipeline, instructions are restarted before their commission to the architectural state. For memory errors, the response depends upon the memory type. The register file 22 is repairable by the exception handler 26 using software. The exception handler 26 is also configured to repair an instruction cache 28 and a data cache 30 using software. The software error management used by the exception handler 26 allows for seamless error logging and flexible response to different types of detected soft errors. In addition, registers 34 are added to the processor. The exception handler 26 and registers 34 operate together with radiation hardening microarchitecture and circuit design enhancements to provide radiation hardness.

The exception handler 26 is invoked by the processor 10 when a soft error is detected. The exception handler 26 is configured to execute software that implements the soft error correction instructions and thereby correct the soft error. Additionally, the exception handler 26 may execute a diagnostic routine for subsequent soft error analysis. The registers 34 are a modification to the standard behavior of the MIPS32 ISA, whereby the value read from general purpose register R0 is always zero. In this architectural extension, the registers 34 behave as the other general purpose registers for instruction execution but do to enable the exception handler 26 to carry out different types of soft error correction instructions. While executing a soft error exception instruction, the exception handler 26 may write a value to R0, including non-zero values, and that value may be read back by another instruction being executed by the exception handler 26. This provides a working register within the exception handler 26. Outside of this exception handler 26, the processor 10 operates in accordance with standard MIPS32 ISA behavior.

The soft error instructions that can be decoded by the instruction decoder 24 and implemented by the exception handler 26 include:
A soft error correction instruction that restores the register file 22 to a previous state prior to a last instruction retirement.
A soft error correction instruction to copy uncorrupted data from one instance of the register file 22 to another instance of the register file 22.
A soft error correction instruction to invalidate (all, and all entries of) the transition lookaside buffers.
A test instruction to allow testability writes to the register file 22 for testing and diagnostic purposes. This instruction allows for the simultaneous writing different values, or for different entries of the register file 22, to test radiation hardening mismatch error checking circuitry.
A read instruction to allow reading a specific instance of the DMR structures in the processor, such as the register file 22 and transition lookaside buffers for testing and diagnostic purposes.
A read instruction to read only a data portion or only a parity portion of the register file 22, for testing and diagnostic purposes.

The (control) registers 34 include:
Registers to allow the disabling of specific soft error checking circuitry in the processor for testing purposes and to allow a work-around of unintended issues that may arise should some of this circuitry not behave as expected.
Registers to log different types of soft errors detected for test and diagnostic purposes.
Registers to hold the address and data of the general purpose register that will be written when the next instruction retires. This register is used to restore the register file 22 to the state it was in prior to the last instruction retirement when restoring the architectural state to a known uncorrupted state.
Registers to hold unique data, parity, and register addresses for each instance of the register file 22 to allow testing its associated radiation hardening mismatch error checking circuitry.
A register to hold the return address of the instruction to be executed following the soft error exception handler that is invoked when a radiation induced error is detected.

The back end of the processor 10 is TMR since program counter (PC) information is critical to restarting instructions after detecting a soft error. Most of the pipeline is DMR, as is evident in FIG. 2. In the speculative pipeline, the register file 22, the caches (e.g., the instruction cache 28, data cache 30), and the processor 10 rely exclusively on error detection to avoid propagating an incorrect architectural state. The register file 22 is configured to flag mismatching store data or write back addresses. For instance, in the case of a SET or SEU within the speculative pipeline or data misread from the register file 22 (whether due to an SEU in the register file 22 or an SET in the dynamic read circuits), the mismatching DMR data are detected where effects are manifested at an architectural state write operation.

On a soft error (SE) exception due to a detected error, the processor 10 is configured to flush in flight instructions—any state in the speculative of circuitry within the DMR pipeline that may be corrupted. The source of the soft error may unknown as the exception is taken. At this point, the dedicated exception handler 26 is invoked, and further interrupts are disabled. In most cases the program counter (PC) of the last retired instruction is saved as the restart address for execution resumption. If the instruction is in the branch delay slot, the restart PC corresponds to the previous branch instruction (using the added pipeline stage R).

At a minimum, the exception handler 26 is configured to restore the state of the register file 22 to the previous state before a last instruction was retired. In this manner, the exception handler 26 is then configured to repair SEU in the register file 22. The exception handler 26 is then configured to invalidate the instruction cache 28 and/or the data cache 32 along with transition lookaside buffers. After execution of the soft error instruction, the exception handler 26 returns a program flow of the processor 10 to the last retired instruction before the soft error (SE) detection. This “scorched Earth” handler policy is very fast, limiting the possibility of nested SE exceptions, even in accelerated beam testing. The minimal embodiment of the exception handler 26, which provides just restart and register file SEU repair, requires 86 instructions including NOPs for exposed hazards, since the processor supports single-cycle transition lookaside buffer and cache invalidates. Full error logging (i.e., stepping through the cache to find latent SEUs) may require 115,328 instructions, but is optional. Since exception handler 26 is in un-cached kernel space, the actual time depends on the system clock and bus latencies. At a 100 MHz bus speed and no wait states, the mandatory handler code implemented by the exception handler 26 requires less than 1 ms.

The SE exception vectors are provided to the same entry address as a reset, soft reset, or non-maskable interrupt (NMI). The exception handler 26 executes in unmapped, un-cached memory avoiding allowing access to potentially corrupted processor resident data in the transition lookaside buffers or caches. For non-SE exceptions, the type is set by the CPO status register. By MIPS software convention, a general purpose register is guaranteed available; however, since a soft error may occur within a reset or NMI handler, this may not be the case. Thus, the standard R0 register behavior is modified in the presently disclosed design—for instructions executed within the exception handler 26, the R0 register is read/write. This base MIPS behavior extension provides exception handler 26 a temporary working register. The entry point for Reset/NMI/SE exceptions is:
LUI $0, 0×0001
BGTZ $0, Offset_To_SEE_Exception_Handler
# branch to exception handler 26 when condition
is # true; otherwise, fall through to reset handler
NOP

For non-SE exceptions, R0 returns to zero, and the code falls through to the Reset/NMI entry code. For SE exceptions, the value returned is non-zero and results in a branch to the SE exception code. Once the exception handler 26 has repaired the corrupted state, it restores the registers it used and executes a return from exception (ERET). Caches (i.e., the instruction cache 28 and/or the data cache 30) and transition lookaside buffers reload normally. Recovery operations may be completely software controlled—data/error logging is optional, and can be altered based on the error type.

With respect to the soft error correction instructions implemented by the exception handler 26, since the last instruction to retire may be corrupted (e.g., its write to the register file 22 may have non-matching DMR data), its state is backed out by the exception handler 26 if the register file 22 was written on that clock cycle. Moreover, the destination register may also have been a source to the instruction, which will be re-executed with the original data. Thus, in the A-stage, the register file 22 value to be replaced in the W-stage is read out via its third read port to prevent a resource conflict with the other two read ports (not shown). To further accelerate error handling, single cycle transition lookaside buffer and cache invalidation instructions have been added. Other added instructions allow register file 22 testability and cache reads and writes for data examination and error validation, as well as SE detection logic testing.

A number of instructions allow access to the DMR arrays individually, bypassing any correction mechanisms. For example, the register file 22 testability write instruction allows for single instance writes. This facilitates testing of the repair and parity error detection circuitry by allowing mismatching writes to the DMR arrays. Additionally, for error reporting, it is necessary to read the register file 22 copies and parity bits independently.

The added RDRFPAR instruction in the following example makes subsequent reads of the register file 22 parity reads only. Also shown is the equivalent RDRFDAT, to allow reading the data only. The read instance instruction (RDINSTx) sets which of the DMR register file 22 or transition lookaside buffer arrays is to be read. There is a hazard on RDRFPAR, but NOPs cannot be uses here, since R0 register will be overwritten (the MIPS NOP is a SLL R0), and R0 contains the base address to dump to (recall R0 does not return zero inside the SE exception). Consequently, SYNC instructions are used instead of NOPS in these cases.

With regard to the registers 34 added to operate the soft error correction instructions, register extensions include error masking for SEE detected error discrimination—specific errors can be disabled. All cache array errors are logged, including control SET and SEU locations. DMR to TMR crossovers in instruction fetch, load/store, and multiply-divide; and instruction execution units are uniquely identified. Finally, DMR RF word line, write-back data mismatches, and data read parity errors are flagged. Added CPO registers include the SEE EPC, which stores the PC to return to after a SEE exception. Other added registers provide BURF with a pointer to the last written RF entry and the data for RF restoration to its pre-error state as well as registers for enhanced error visibility. The CPO error log registers are dumped as follows:
MFCO $5, $9 #sel ¼ 110, R5<-Error Log 1
SW $5, 0($1)
ADDI $1, $1, 0×0004 # increment R1 to next word
MFCO $5, $9 #sel ¼ 111, R5<-Error Log 2
SW $5, 0($1)

At this point, the base address for the next dump of the processor state to memory is updated to prepare for the next SE exception. Then the CPO ErrCtl register is saved in R1 and then cleared. Clearing the WST bit in this register ensures that the added cache global invalidate instructions are properly decoded. After the cache invalidations, the ErrCtl register is restored. Since this register is only used for testing, this step may not really be necessary, but it is possible some code was using it when the soft error was detected.
MFCO $1, $26 #sel ¼ 000, R1<-ErrCtl
LUI $0, 0×0000 #R0<-0
MTCO $0, $26
NOP
NOP

With regard to special cases handled by the exception handler 26, restarted load and store instructions are specially handled by the hardware—writes to I/O devices may have side effects and thus cannot be re-issued to the bus interface 16. Incoming bus data from load instructions are also TMR so that the data can be used without re-issuing the operation to the external bus; as such operations may also have system level side effects. The next PC logic (which includes the ALU adder 36) is DMR, minimizing the hardware overhead, with a transition to a TMR PC occurring at the front-end of the processor 10 to provide a non-corrupted PC at the back end of the processor, which provides the restart address when the pipeline is flushed. A separate PC pipeline is maintained (in the IEU) for multiply divide unit (MDU) instructions (pipeline stages M through W), since the W-stage PC for an MDU instruction is required for some SE exception return cases.

The MDU pipeline runs concurrently with the integer pipeline and its depth (particularly for divides) is instruction dependent, so the necessary logic to allow it to complete despite an SE exception in the DMR pipeline is included. This is critical, as the register file 22 may no longer contain the divide instruction inputs when the MDU pipeline is restarted. This restart information is TMR.

The data cache is written simultaneously with a store buffer 38 when no array conflict arises. Since the hit/miss state is initially unknown, the tag is looked up in the pipeline stage M. On a hit, the data array is written at the first subsequent cycle at which the data cache 32 is not executing a load. All other writes to TMR architectural structure require two clock cycles.

When writing to the CPO registers in the register 34, a dual-to-triple redundant crossover occurs in the pipeline stage A, and the actual register update is in the pipeline stage W. This allows the prevention of errors that originate on the DMR side of the crossover logic from making it into the CPO registers. Once updated in the pipeline stage W, a TMR self-correction mechanism ensures the integrity of these registers.

Added CPO registers in the registers 34 include error logs 1 and 2 for reporting error sources accurately, and error masks 1 and 2. Error masks 1 and 2 allow specific errors to be ignored. The error log registers allow soft-error discrimination. Errors at DMR to TMR crossovers for instruction fetch, load/store, multiply-divide, and instruction execution are separated. Write-back data mismatches, and scrub/repair port data read parity errors are flagged in error log registers. The CPO register stores the PC to return to after an SE exception. RF data and address backup registers store the RF entry and value that was overwritten by the instruction that had mismatching data. These provide the backup register file instruction with data and register to restore the register file 22 to its correct state.

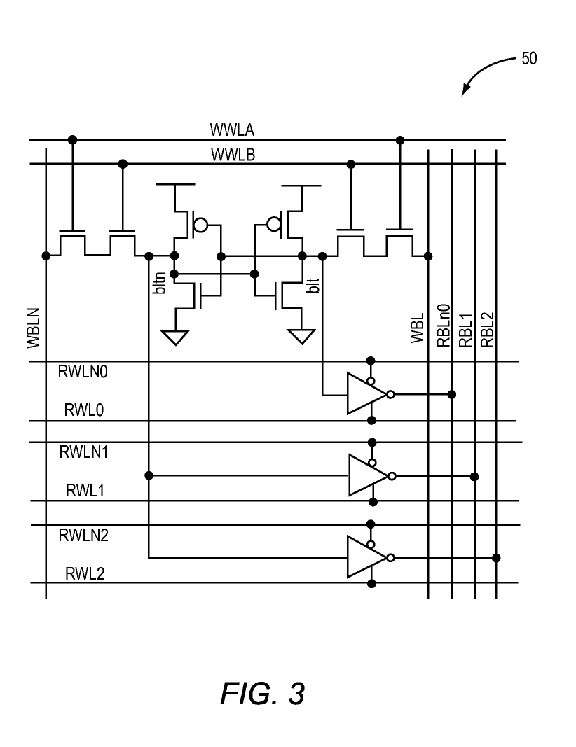

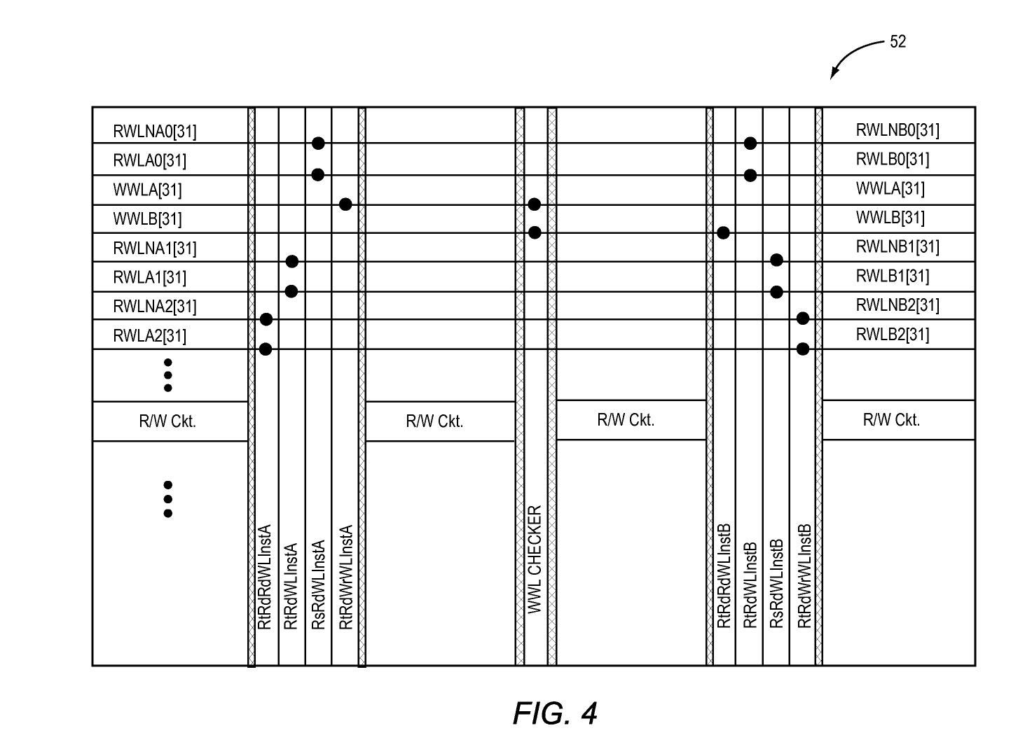

Referring now to FIGS. 3 and FIG. 4, FIG. 3 illustrates a register file cell 50 in the register file 22 shown in FIG. 2, while FIG. 4 illustrates an exemplary description of a floorplan 52 of the register file 22 shown in FIG. 2. To design the register file 22 shown in FIG. 2, the register file cells (like the register file cell 50 shown in FIG. 3) are compatible with the cell library pitch, allowing columns to use an existing cell library. The register file 22 shown in FIG. 2 has three read ports, with the third Rd/Rt read port allowing a pre-emptive read of registers 34 (shown in FIG. 2) that will be written in the next pipeline stage W.

When there is no pending write, ports are read and parity is checked to provide a register file scrubbing function, alleviating the possibility of accumulated errors from separate strikes. Designs for register file decoders are synthesized to further ease process porting. The caches (i.e., the instruction cache 28 and the data cache 32 shown in FIG. 2) are designed using an identical scheme but with a single read port. The static read scheme dissipates 35.8% less power than a dynamic readout and uses the same area for a single read port. One drawback of static operation may be the inability to generate positive and negative tag values simultaneously. This results in a slowdown of 150 ps, equivalent to seven gate delays on the low leakage power foundry process, for the tag address compares. A key difficulty in using register files for caches is the ½ select problem created by interleaving. The DMR scheme allows bits to be stored in adjacent cells with a simple write gate to allow byte cache writes. A cache error in one copy is caught on its store to the register file 22 (shown in FIG. 2) requiring no additional check circuits.

Those skilled in the art will recognize improvements and modifications to the preferred embodiments of the present disclosure. All such improvements and modifications are considered within the scope of the concepts disclosed herein and the claims that follow.

What is claimed is:

1. A processor, comprising:
an instruction decoder configured to receive one or more soft error correction instructions and decode the one or more soft error correction instructions; and
an exception handler configured to execute the one or more soft error correction instructions so as to correct one or more soft errors.

2. The processor of claim 1 wherein the exception handler is configured to execute the one or more soft error correction instructions by implementing software to perform the one or more soft error correction instructions.

3. The processor of claim 1 further comprising a register file and wherein the one or more soft error correction instructions comprise an instruction to restore the register file to a previous state.

4. The processor of claim 3 wherein the previous state is prior to a last instruction retirement.

5. The processor of claim 1 further comprising a dual mode redundant (DMR) register file wherein the one or more software error instructions comprise an instruction to copy data from an uncorrupted instance of the DMR register file to a corrupted instance of the DMR register file.

6. The processor of claim 1 further comprising a dual mode redundant (DMR) structures wherein the one or more soft error correction instructions comprise a read instruction for reading a specific instance of the DMR structures.

7. The processor of claim 6 wherein the DMR structures comprise a DMR register file and a transition lookaside buffer.

8. The processor of claim 1 further comprising a register file wherein the one or more soft error correction instructions comprise a read instruction to read only a data portion of the register file.

9. The processor of claim 1 further comprising a register file wherein the one or more soft error correction instructions comprise a read instruction to read only a parity portion of the register file.

10. The processor of claim 1 further comprising registers that hold data to perform at least one of the one or more soft error correction instructions.

11. The processor of claim 10 wherein the registers comprise registers to allow the disabling of specific soft error checking circuitry in the processor.

12. The processor of claim 10 wherein the registers comprise registers to log different types of soft errors detected for test and diagnostic purposes.

13. The processor of claim 10 further comprising a general purpose register wherein the registers comprise registers to hold addresses of the general purpose register that will be written when a next instruction retires.

14. The processor of claim 13 further comprising a register file wherein the registers to hold addresses of the general purpose register are configured to be used to restore the register file to a previous state.

15. The processor of claim 14 wherein the previous state is prior to a last instruction retirement.

16. The processor of claim 10 further comprising a general purpose register wherein the registers comprise registers to hold data of the general purpose register that will be written when a next instruction retires.

17. The processor of claim 16 further comprising a register file wherein the registers to hold data of the general purpose register are configured to be used to restore the register file to a previous state.

18. The processor of claim 17 wherein the previous state is prior to a last instruction retirement.

19. The processor of claim 10 further comprising a dual mode redundant (DMR) register file wherein the registers comprise registers to hold unique data, parity, and register addresses for each instance of the DMR register file.

20. The processor of claim 10 wherein the registers comprise a register to hold a return address of an instruction to be executed by the processor when a radiation induced error is detected.
